(19) United States
(12) Patent Application Publication
(10) Pub. No.: US 2020/0103770 A1
(43) Pub. Date: Apr. 2, 2020

(54) A SYSTEM FOR CLEANING A SUBSTRATE SUPPORT, A METHOD OF REMOVING MATTER FROM A SUBSTRATE SUPPORT, AND A LITHOGRAPHIC APPARATUS

(71) Applicant: ASML NETHERLANDS B.V., Veldhoven (NL)

(72) Inventors: Tiannan GUAN, Best (NL); Tjarco LINDEIJER, Eindhoven (NL); Bert Dirk SCHOLTEN, Best (NL); André SCHREUDER, Eindhoven (NL)

(73) Assignee: ASML NETHERLANDS B.V., Veldhoven (NL)

(21) Appl. No.: 16/615,868

(22) PCT Filed: May 23, 2018
(86) PCT No.: PCT/EP2018/063447

§ 371 Date: Nov. 22, 2019

(30) Foreign Application Priority Data
Jun. 8, 2017 (EP) 17175095.3

(51) Int. Cl. G03F 7/20

(52) U.S. Cl. CPC G03F 7/70925

(57) ABSTRACT

A system for cleaning a substrate support having a plurality of projections extending in a first direction each with a terminal surface arranged to be in contact with the substrate, the system including: a treatment tool arranged for relative movement in a second direction orthogonal to the first direction and a third direction orthogonal to the first and second directions over the terminal surfaces of the projections to remove matter from the substrate support; and a controller to control the treatment tool dependent upon a position in the second and third directions of the treatment tool relative to the substrate support such that the removal amount from each of the plurality of projections is maintained substantially constant from one projection to another.

### CROSS-REFERENCE TO RELATED APPLICATIONS

This application claims priority of EP application 17175095.3 which was filed on Jun. 8, 2017 and which is incorporated herein in its entirety by reference.

### FIELD

The present invention relates to a system for cleaning a substrate support, a method of removing matter from a substrate support, and a lithographic apparatus. The removed matter may be contaminants and/or material of the substrate support.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer). To project a pattern on the substrate the lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm. A lithographic apparatus, which uses extreme ultraviolet (EUV) radiation, having a wavelength within a range of 4 nm to 20 nm, for example 6.7 nm or 13.5 nm, may be used to form smaller features on the substrate than a lithographic apparatus which uses, for example, radiation with a wavelength of 193 nm.

The substrate is clamped onto a substrate support of a substrate table in the lithographic apparatus when transferring a pattern from the patterning device. A substrate support conventionally has a plurality of projections extending in a first (z) direction (called burls) to support the substrate. The total area of terminal surfaces of the projections that contact the substrate thereby to support the substrate is small compared to the total area of a substrate. Therefore, the chance that a contaminant particle randomly located on the surface of the substrate or the substrate support is trapped between a projection and the substrate is small. Also, in manufacture of the substrate support, the tops of the projections can be made more accurately coplanar than a large surface can be made accurately flat.

When a substrate is first loaded onto the substrate support in preparation for exposure, the substrate is supported by so-called e-pins which hold the substrate at multiple positions. To load the substrate onto the substrate support, the e-pins are retracted so that the substrate is supported by projections of the substrate support.

The flatness of the terminal surfaces of the projections (i.e. how close to being in the same plane all of the terminal surfaces of the projections are) is important. This is because any variation in the flatness of the projections is transmitted to the top surface of the substrate which is subjected to irradiation. The flatness of the substrate can also be reduced if there is contamination between the terminal surface of a projection and the substrate.

A substrate support is periodically cleaned by moving a treatment tool over the terminal surfaces (in directions orthogonal to the first direction), thereby to remove contamination from the substrate support. One such treatment tool is disclosed in WO 2016/081951. The treatment tool may be rotated at the same time as it is moved over the substrate support. For example the treatment tool may be arranged such that a surface which contacts the terminal surfaces of the projections rotates in a plane parallel to the plane in which the terminal surfaces of the projections lie. The footprint of the treatment tool is smaller than that of the substrate support so that the substrate support and treatment tool are moved relative to one another during the treatment. The treatment tool may be made, for example, of granite or SiSiC.

### SUMMARY

It is desirable, for example, to provide an improved treatment tool for maintaining the flatness of a substrate support.

According to an aspect of the invention, there is provided a system for cleaning a substrate support comprising a plurality of projections extending in a first direction each with a terminal surface arranged to be in contact with the substrate, the system comprising: a treatment tool arranged for relative movement in a second direction orthogonal to the first direction and a third direction orthogonal to the first direction and the second direction over the terminal surfaces of the projections thereby to remove matter from the substrate support; a controller adapted to control the treatment tool dependent upon a position in the second and third directions of the treatment tool relative to the substrate support such that the removal amount from each of the plurality of projections is maintained substantially constant from one projection to another.

According to an aspect of the invention, there is provided a lithographic apparatus comprising: a substrate support comprising a plurality of projections extending in a first direction each with a terminal surface arranged to be in contact with a substrate thereby to support the substrate; a treatment tool arranged for relative movement in a second direction orthogonal to the first direction and a third direction orthogonal to the first direction and the second direction over the terminal surfaces of the projections thereby to remove matter from the substrate support; an actuator for moving the substrate support and/or treatment tool in the first direction relative to each other; and a controller adapted to control the actuator dependent upon a position in the second and third directions of the treatment tool relative to the substrate support.

According to an aspect of the invention, there is provided a method of removing matter from a substrate support which comprises a plurality of projections extending in a first direction each with a terminal surface arranged to be in contact with the substrate thereby to support the substrate, the method comprising: moving a treatment tool in a second direction orthogonal to the first direction and third direction orthogonal to the first direction and the second direction over the terminal surfaces of the projections thereby to remove matter from the substrate support; controlling an actuator such that a magnitude of a force between the substrate support and treatment tool varies the treatment tool dependent upon a position in the second and third directions of the treatment tool relative to the substrate support such that the removal amount from each of the plurality of projections is maintained substantially constant from one projection to another.

According to an aspect of the invention, there is provided a method of removing matter from a substrate support which comprises a plurality of projections extending in a first direction each with a terminal surface arranged to be in contact with the substrate thereby to support the substrate, the method comprising: moving a treatment tool in a second direction orthogonal to the first direction and third direction orthogonal to the first direction and the second direction over the terminal surfaces of the projections thereby to remove matter from the substrate support; measuring deviations from a desired surface topography of the substrate supported by the substrate support; and controlling the treatment tool dependent upon a position in the second and third directions of the treatment tool relative to the substrate support and dependent upon the measured deviation at the position thereby to reduce or maintain differences in measured deviation from one projection to another.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 schematically depicts a lithographic apparatus;

FIG. 2 depicts in plan a substrate support and a superimposed treatment tool;

FIG. 3 depicts a map of deviations from a given plane in the first direction of the position of terminal surfaces of projections of a substrate support cleaned using a conventional treatment tool;

FIG. 4 is a graph showing the variation of number of projections under a treatment tool with time during a full cleaning cycle of a substrate support 60;

FIG. 5 is a chart of normalized force distribution on the treatment tool for each location during a full substrate support cleaning cycle; and

FIG. 6 is a schematic illustration of a system for cleaning a substrate support.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

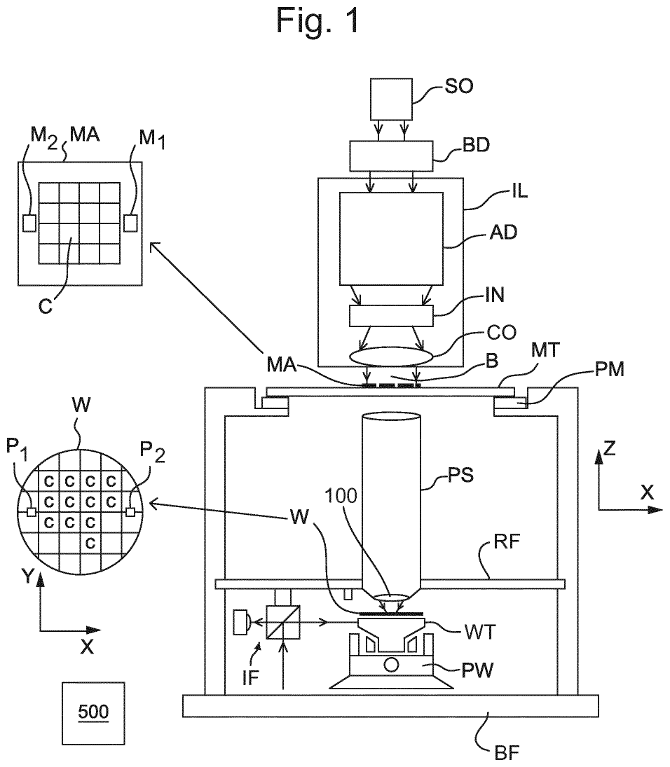

FIG. 1 schematically depicts a lithographic apparatus of an embodiment. The apparatus comprises:

optionally, an illumination system (illuminator) IL configured to condition a radiation beam B (e.g. UV radiation or DUV radiation);

a support structure (e.g. a mask table) MT constructed to support a patterning device (e.g. a mask) MA and connected to a first positioner PM configured to accurately position the patterning device MA in accordance with certain parameters;

a support table, e.g. a sensor table to support one or more sensors or a substrate table or wafer table WT constructed to hold a substrate (e.g. a resist-coated production substrate) W, connected to a second positioner PW configured to accurately position the surface of the table, for example of a substrate W, in accordance with certain parameters; and a projection system (e.g. a refractive projection lens system) PS configured to project a pattern imparted to the radiation beam B by patterning device MA onto a target portion C (e.g. comprising part of, one, or more dies) of the substrate W.

The lithographic apparatus may be of a type wherein at least a portion of the substrate W may be covered by an immersion liquid having a relatively high refractive index, e.g. water such as ultra pure water (UPW), so as to fill an immersion space between the projection system PS and the substrate W. An immersion liquid may also be applied to other spaces in the lithography apparatus, for example, between the patterning device MA and the projection system PS Immersion techniques can be used to increase the numerical aperture of projection systems. The term “immersion” as used herein does not mean that a structure, such as a substrate W, must be submerged in immersion liquid; rather “immersion” only means that an immersion liquid is located between the projection system PS and the substrate W during exposure. The path of the patterned radiation beam B from the projection system PS to the substrate W is entirely through immersion liquid. In an arrangement for providing immersion liquid between a final optical element of the projection system PS and the substrate W a liquid confinement structure extends along at least a part of a boundary of an immersion space between the final optical element of the projection system PS and the facing surface of the stage or table facing the projection system PS.

In operation, the illuminator IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system”.

The lithographic apparatus may be of a type having two or more support tables, e.g., two or more support tables or a combination of one or more support tables and one or more cleaning, sensor or measurement tables. For example, the lithographic apparatus is a multi-stage apparatus comprising two or more tables located at the exposure side of the projection system, each table comprising and/or holding one or more objects. In an example, one or more of the tables may hold a radiation-sensitive substrate. In an example, one or more of the tables may hold a sensor to measure radiation from the projection system. In an example, the multi-stage apparatus comprises a first table configured to hold a radiation-sensitive substrate (i.e., a support table) and a second table not configured to hold a radiation-sensitive substrate (referred to hereinafter generally, and without limitation, as a measurement, sensor and/or cleaning table). The second table may comprise and/or may hold one or more objects, other than a radiation-sensitive substrate. Such one or more objects may include one or more selected from the following: a sensor to measure radiation from the projection system, one or more alignment marks, and/or a cleaning device (to clean, e.g., the liquid confinement structure).

In operation, the radiation beam B is incident on the pattern (design layout) present on patterning device (e.g., mask) MA, which is held on the support structure (e.g., mask table) MT, and is patterned by the patterning device MA. Having traversed the patterning device MA, the radiation beam B passes through the projection system PS, which focuses the beam onto a target portion C of the substrate W. With the aid of the second positioner PW and position sensor IF (e.g. an interferometric device, linear encoder, 2-D encoder or capacitive sensor), the substrate table WT can be moved accurately, e.g. so as to position different target portions C in the path of the radiation beam B at a focused and aligned position. Similarly, the first positioner PM and another position sensor (which is not explicitly depicted in FIG. 1) can be used to accurately position the patterning device MA with respect to the path of the radiation beam B. Patterning device MA and substrate W may be aligned using patterning device alignment marks M1, M2 and substrate alignment marks P1, P2. Although the substrate alignment marks P1, P2 as illustrated occupy dedicated target portions, they may be located in spaces between target portions C (these are known as scribe-lane alignment marks). A controller 500 controls the overall operations of the lithographic apparatus and in particular performs an operation process described further below. Controller 500 can be embodied as a suitably-programmed general purpose computer comprising a central processing unit, volatile and non-volatile storage means, one or more input and output devices such as a keyboard and screen, one or more network connections and one or more interfaces to the various parts of the lithographic apparatus. It will be appreciated that a one-to-one relationship between controlling computer and lithographic apparatus is not necessary. One computer can control multiple lithographic apparatuses. Multiple networked computers can be used to control one lithographic apparatus. The controller 500 may also be configured to control one or more associated process devices and substrate handling devices in a lithocell or cluster of which the lithographic apparatus forms a part. The controller 500 can also be configured to be subordinate to a supervisory control system of a lithocell or cluster and/or an overall control system of a fab.

The substrate table WT comprises a substrate support 60. The substrate W is conventionally clamped to the substrate support 60 during exposures. Two clamping techniques are commonly used. In vacuum-clamping a pressure differential across the substrate W is established, e.g., by connecting the space between the substrate support 60 and the substrate W to an under-pressure that is lower than a higher pressure above the substrate W. The pressure difference gives rise to a force holding the substrate W to the substrate support 60. In electrostatic clamping, electrostatic forces are used to exert a force between the substrate W and the substrate support 60. Several different arrangements are known to achieve this. In one arrangement a first electrode is provide on the lower surface of the substrate W and a second electrode on the upper surface of the substrate support 60. A potential difference is established between the first and second electrodes. In another arrangement two semi-circular electrodes are provided on the substrate support 60 and a conductive layer is provided on the substrate W. A potential difference is applied between the two semi-circular electrodes so that the two semi-circular electrodes and the conductive layer on the substrate W act like two capacitors in series.

To load a substrate W onto the substrate support 60 for exposures, the substrate W is picked up by a substrate handler robot and lowered onto a set of e-pins. The e-pins project through the substrate support 60. The e-pins are actuated so that they can extend and retract. The e-pins may be provided with suction openings at their tips to grip the substrate W. The e-pins may comprise six e-pins spaced around the center of the substrate support 60. Once the substrate W has settled on the e-pins, the e-pins are retracted so that the substrate W is supported by projections 20 of the substrate support 60.

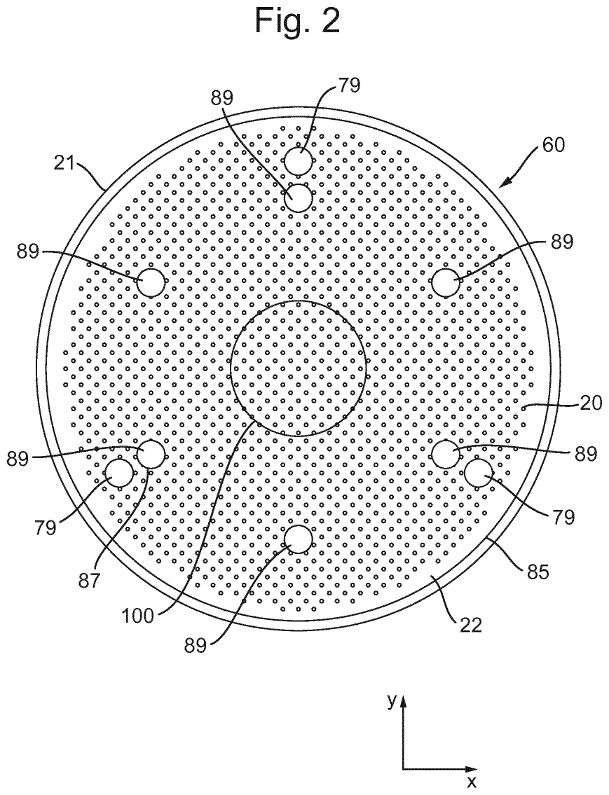

FIG. 2 depicts a substrate support 60 for use in a lithographic apparatus. The substrate support 60 supports a substrate W. The substrate support 60 comprises a main body 21. The main body 21 has a main body surface 22. A plurality of projections 20 are provided projecting from the main body surface 22 in a first (z) direction. A terminal surface of each projection 20 engages (contacts) with the substrate W. The terminal surfaces of the projections 20 substantially conform to a support plane and support the substrate W. Main body 21 and projections 20 may be formed of SiSiC, a ceramic material having silicon carbide (SiC) grains in a silicon matrix. Alternatively, main body 21 and projections 20 may be formed of SiC.

A plurality of through-holes 89 may be formed in the main body 21. Through-holes 89 allow the e-pins to project through the substrate support 60 to receive the substrate W. Through-holes 89 may allow the space between a substrate W and the substrate support 60 to be evacuated. Evacuation of the space between a substrate W and the substrate support 60 can provide a clamping force, if the space above the substrate W is not also evacuated. The clamping force holds the substrate W in place. If the space above the substrate W is also evacuated, as would be the case in a lithographic apparatus using EUV radiation, electrodes can be provided on the support 60 WT to form an electrostatic clamp.

Further through-holes 79 are illustrated in FIG. 2. Such through-holes may be present, for example, to allow the substrate support 60 to be fixed to the substrate table WT, for example using bolts. Alternatively the substrate support 60 can be fixed to substrate table WT by vacuum clamping.

During cleaning of the substrate support 60 with a treatment tool 100 such as disclosed in WO 2016/081951, the treatment tool 100 is supported on the terminal surfaces of the projections 20. That is, the treatment tool 100 rests on the substrate support 60 by its own weight. FIG. 2 shows a treatment tool 100 superimposed over the substrate support 60.

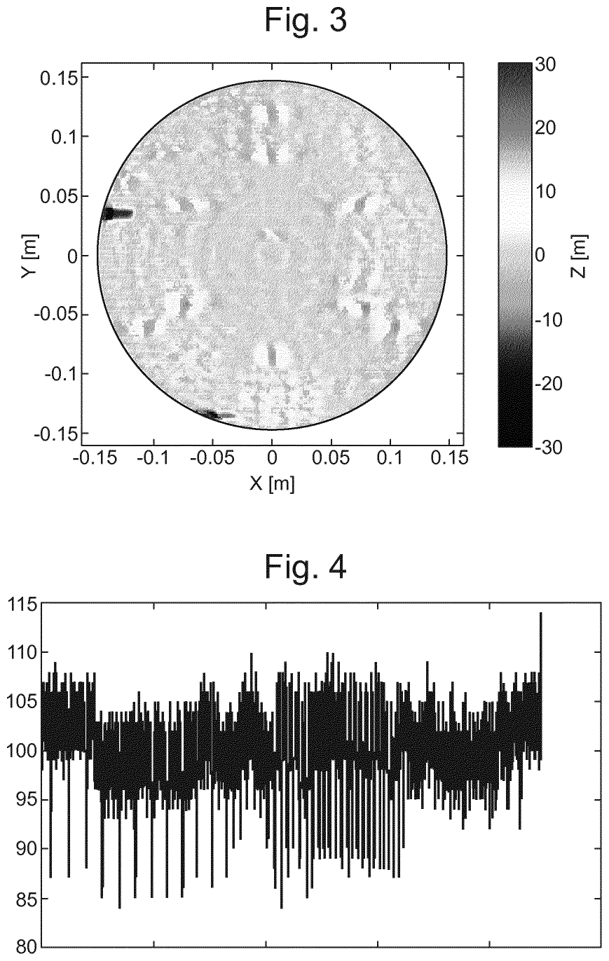

FIG. 3 is a map of the relative height of the terminal surfaces of the projections 20 of a substrate support 60 cleaned using a treatment tool 100 resting its weight on the substrate support 60. As can be seen, at the location of through-holes 89 and further through-holes 79 significant deviations from flat are present. The present inventors have noticed this phenomenon for the first time and have concluded that it is a result of the treatment tool 100 having its weight supported by the projections 20. As the treatment tool 100 moves over the surface of the substrate support 60, the number of projections 20 under the treatment tool 100 varies. For example when the treatment tool 100 is in the center, in plan, as illustrated, of the substrate support 60 there are many projections 20 under the treatment tool 100 in an uninterrupted regular pattern. However, when the treatment tool 100 passes over one or more of the through-holes 89 or further through-holes 79 the number of projections 20 under the treatment tool 100 decreases. As a result, the force on each individual projection 20 from the treatment tool 100 is greater at locations where the treatment tool 100 is positioned above a through-hole 89 and/or further through-hole 79 compared to where the treatment tool 100 is supported by more projections 20 in locations without any through-holes 89 or further through-holes 79. This extra force leads to extra wear of the terminal surfaces of the projections 20 in locations around the through-holes 89 and further through-holes 79 thereby adversely affecting the flatness of the substrate support 60. Although some deviation from perfect flatness can be tolerated, over time the deviation from flatness will mean that the substrate support 60 falls outside of specification and must be replaced.

FIG. 4 shows the variation in the number of projections 20 under the treatment tool 100 as a function of time during a full cleaning cycle. The average number of projections 20 under the treatment tool 100 is about 100 but as can be seen the number varies between about 85 and 110. If the treatment tool 100 has its weight completely supported by the substrate support 60, this leads to a variation of up to about 20% in the force applied to the projections 20.

In the present invention measures are taken to mitigate against the variation in number of protections 20 under the treatment tool 100 as a function of relative position in the second and third directions of the treatment tool 100 relative to the substrate support 60. In particular the controller 500 is provided to control the treatment tool 100 dependent upon a position in the second and third directions of the treatment tool 100 relative to the substrate support 60 such that the removal from each of the plurality of projections 20 is maintained substantially constant from one projection 20 to another. Below described in detail is a way of controlling a force between the treatment tool 100 and the substrate support 60 such that the removal amount from each of the plurality of projections 20 can be controlled, for example to maintain the amount of matter removed substantially constant from one projection 20 to another. The detailed embodiment involves changing a magnitude of a force between substrate support 60 and the treatment tool 100 as a function of position in the second and third directions of the treatment tool 100 relative to the substrate support 60. However, other ways of controlling the removal amount from each of the plurality of projections 20 are possible. Two such examples are changing the speed of rotation of the treatment tool 100 around the first direction. For example, during a conventional cleaning cycle the treatment tool 100 would be rotated at a constant speed of say 30 RPM. By varying the rotation speed say between 0 and 60 RPM dependent upon position of the treatment tool 100 relative to the substrate support 60, it is possible to vary the amount of matte removed from one position to another. For example increasing the rotation speed will increase the removal rate and thereby the amount of matter removed from each of the plurality of projections 20 under the treatment tool 100 at that time assuming the treatment tool 100 spends the same amount of time at each position and force is constant. Reducing the rotation speed will conversely reduce the amount of matte removed from the projections 20 under the treatment tool 100 for a given amount of time. In an alternative or additional embodiment the amount of time the treatment tool 100 is in each position relative to the substrate support 60 (in the second and third directions) is varied. This can be achieved by changing the speed with which the substrate table WT moves under the treatment tool 100 (assuming the treatment tool 100 is stationary in the second and third directions and the substrate table WT moves the substrate support 60 in the second and third directions relative to the treatment tool 100). A typical relative movement speed might be 30 mm/s. By varying the moving speed between 0 and 30 mm/s the amount of time the treatment tool 100 is in each position relative to the substrate support 60 can be varied considerably. Moving the substrate support 60 faster results in less removal of matter whereas moving the substrate support 60 slower results in more removal of matter (assuming rotation of the treatment tool 100 and force are constant). Although the embodiment described below refers to the magnitude of force between the substrate support 60 and the treatment tool 100 being varied during a cleaning cycle, the same description is applicable additionally or alternatively to varying the rotation speed and/or amount of time, as described above.

Thus for example when the treatment tool 100 is positioned over a through hole 89 or further through hole 79 the speed of rotation and/or amount of time and/or magnitude of force between the substrate support 60 and the treatment tool 100 can be reduced thereby to account for the lower number of projections 20 under the treatment tool 100 in that position compared to other positions.

In an embodiment a magnitude of a force between the substrate support 60 and the treatment tool 100 is varied during a cleaning cycle. The magnitude of the force between the substrate support 60 and treatment tool 100 is varied dependent upon the position of the treatment tool 100 relative to the substrate support 60. In particular, the magnitude is varied dependent upon a position in the second (x) and third (y) directions (orthogonal to each other and to the first (z) direction) of the treatment tool 100 relative to the substrate support 60. In this way the forces applied by the treatment tool 100 to each terminal surface can be maintained more constant than in the case of passive cleaning where the weight of the treatment tool 100 is supported by the substrate support 60. As a result, the matter removal rate from the projections 20 is maintained substantially constant from one projection 20 to another.

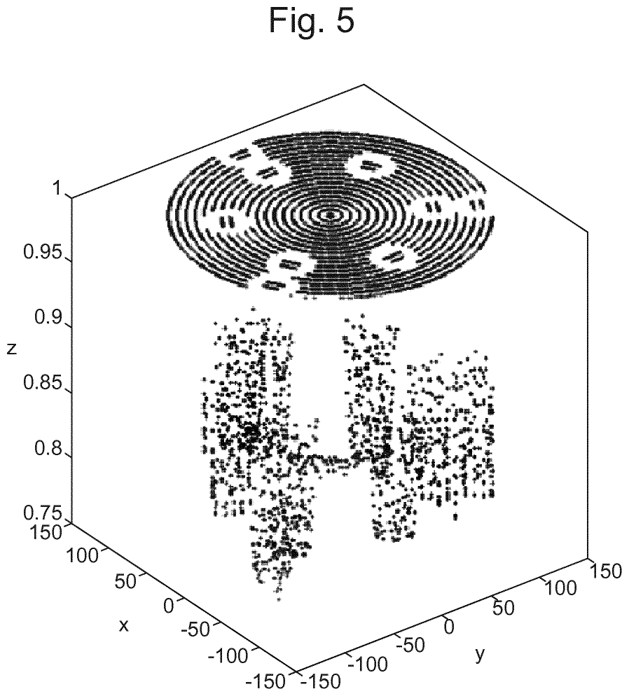

FIG. 5 shows an example force distribution used on the treatment tool 100 as a function of position. Every point represents a position of a center point (in plan) of the treatment tool 100 relative to the substrate support 60 during a full cleaning cycle of the substrate support 60. When the treatment tool 100 is fully in contact with the terminal surfaces of the projections 20, the reaction force experienced by the treatment tool 100 from the projections 20 is normalized to be equal to 1. When the treatment tool 100 passes over a through-hole 89 or further through-hole 79, the area where the treatment tool 100 contacts the substrate support 60 is divided by the total area of the treatment tool 100 itself. This ratio multiplied by a constant parameter to calculate the force reduction required to keep the force applied to each projection 20 constant and thereby the matter removal rate constant at those locations.

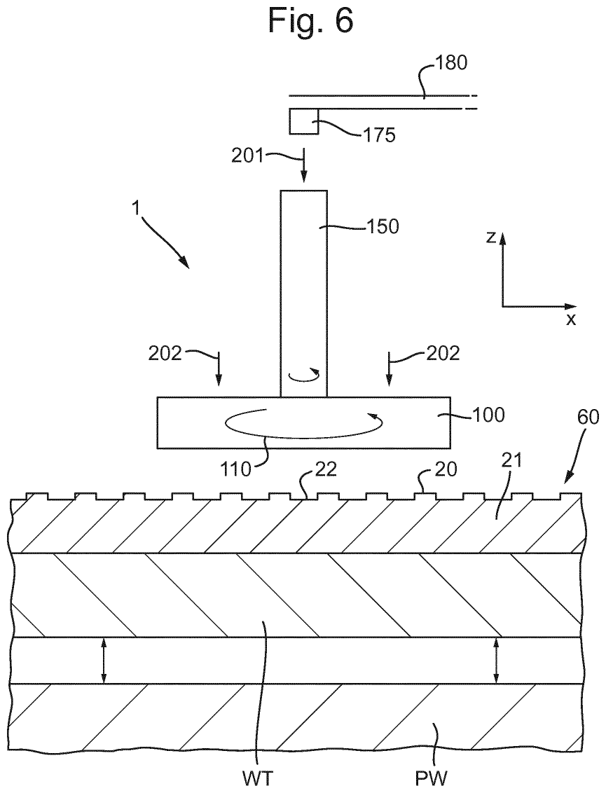

FIG. 6 illustrates schematically a system 1 for cleaning a substrate support 60. The treatment tool 100 is arranged for rotation around the z axis as illustrated by arrow 110. This is effected by rotation of a shaft 150. The treatment tool 100 can contact the terminal surfaces of the projections 20 of the substrate support 60. Matter is removed due to the movement of the treatment tool 100 over the terminal surfaces of the projections 20 mainly due to the rotation of the treatment tool 100. Relative translational movement in the x and y directions of the treatment tool 100 relative to the substrate support 60 means that the whole top surface of the substrate support 60 can be moved under the treatment tool 100 such that all projections 20 can be cleaned.

Thus there is disclosed a system 1 for cleaning a substrate support 60 comprising a plurality of projections 20 extending in a first direction each with a terminal surface arranged to be in contact with the substrate W, the system 1 comprising: a treatment tool 100 arranged for relative movement in a second direction orthogonal to the first direction and a third direction orthogonal to the first direction and the second direction over the terminal surfaces of the projections 20 thereby to remove matter from the substrate support 60; an actuator (e.g. force control element 175 or second positioner PW) for applying a variable force in the first direction between the treatment tool 100 and the substrate support 60; and a controller 500 adapted to control a magnitude of the variable force applied by the actuator dependent upon a position in the second and third directions of the treatment tool relative to the substrate support.

In an embodiment the system 1 for cleaning the substrate support 60 is positioned within a lithographic apparatus. Therefore the substrate support 60 is positioned on a substrate table WT which can be moved using the second positioner PW. However, the system 1 for cleaning the substrate support 60 may be positioned outside of a lithographic apparatus. The advantage of positioning the system 1 for cleaning a substrate within a lithographic apparatus is that cleaning processes are less disruptive to use of the lithographic apparatus such that the cleaning process results in less downtime of the lithographic apparatus.

A force control element 175 applies a force in the first (z) direction between the treatment tool 100 and a reference portion 180 of the lithographic apparatus. The reference portion 180 is fixed in the first (z) direction relative to the lithographic apparatus during use of the treatment tool 100. The reference portion 180 may be a frame or another component and the force control element 175 applies a force between the reference portion 180 and the treatment tool 100 to move the treatment tool 100 closer to or further away from the reference portion 180 in the first (z) direction. In a preferred embodiment the force control element 175 applies the force along the axis of the shaft 150 (which is attached to the treatment tool 100 at the mass center of the treatment tool 100) as illustrated by arrow 201. In an alternative or additional embodiment the force control element 175 applies the force off axis, for example on the top of the treatment tool 100 as illustrated by arrows 202. In this embodiment one or more contacting force delivery parts may be present for the application of the forces 202. The forces 202 must be well aligned, as misalignment of the forces 202 may cause unwanted torque momentum on the treatment tool 100 thereby generating unwanted and potentially uncontrollable wear patterns on the substrate support 60.

The force control element 175 may be integrated within the system 1 for cleaning the substrate support 60, optionally within the lithographic apparatus. However, the force control element 175 may also be located outside of the system 1 for cleaning the substrate support 60 and optionally additionally outside of the lithographic apparatus.

A passive embodiment and an active embodiment will now be described. In the embodiment, the force control element 175 applies a biasing force on the treatment tool 100 which has a magnitude which varies as a function of the distance between the treatment tool 100 and the reference portion 180. In one embodiment the force control element 175 is a spring. By specifying the stiffness of the spring, at a certain amount of compression the required down force on the treatment tool 100 ensures that the correct force between the treatment tool 100 and the substrate support 60 is applied. The compression length of the force control element 175 depends upon the position in the z direction of the substrate support 60 relative to the reference portion 180 (which is equivalent to the distance in the z direction of the substrate support 60 relative to the stationary parts of the lithographic apparatus, such as the base frame BF). In this embodiment the second positioner PW is used to control the height of the substrate table WT (distance of the substrate support 60 from the reference portion 180) and thereby in turn the height of the substrate support 60. This thereby controls the force applied by the force control element 175 between the reference portion 180 and the treatment tool 100. Thus when the treatment tool 100 moves over an area with a through-hole 89 or a further through-hole 79 from a position with no such through-holes, in order to reduce the force on each of the terminal surfaces (which would otherwise increase), the second positioner PW moves the substrate table WT away from the reference portion 180. Thereby the magnitude of the biasing force applied by the passive force control element 175 between the reference portion 180 and the treatment tool 100 is lowered and thereby the force on the terminal surfaces is maintained constant.

In a preferred embodiment the actuators of the second positioner PW for moving the substrate table WT in the z direction are force controlled. In this way the height of the substrate table WT during the cleaning cycle will be determined by a force which is programmed with respect to the x and y position of the treatment tool 100 relative to the substrate support 60. In this way a specific pressure map such as that illustrated in FIG. 5 may easily be accomplished thereby maintaining the flatness of the substrate support 60.

In an embodiment the second position at PW additionally moves the substrate table WT in the x and y directions during a cleaning procedure whilst the treatment tool 100 is stationary (relative to the remainder of the lithographic apparatus and the reference portion 180) during the cleaning cycle. In an embodiment where the system 1 for cleaning the substrate support 60 is outside of a lithographic apparatus a positioner such as the second positioner PW may be provided for moving the substrate support 60 (optionally removed from the substrate table WT) in the first (z) direction. That positioner may additionally move the substrate support 60 in the second and third (x and y) directions. In an alternative arrangement a positioner may translationally move the treatment tool 100 in the second and third (x and y) directions.

In the active embodiment one or more actuators move the substrate support 60 and/or treatment tool 100 in the first (z) direction relative to each other thereby to apply a variable force in the z direction between the treatment tool 100 and the substrate support 60. As with all other embodiments the controller 500 controls the magnitude of the variable force applied by the at least one actuator dependent upon a position in the x and y directions of the treatment tool 100 relative to the substrate support 60.

The controller 500 controls the lithographic apparatus and/or system 1 for cleaning such that a force applied between the treatment tool 100 and the substrate support 60 decreases when the treatment tool 100 moves from a location with a certain number of the plurality of projections 20 under it to a location with a lower number of the plurality of projections 20 under it than the certain number and vice versa. In an embodiment the treatment tool 100 is in a fixed position in the first (z) direction (for example relative to the reference portion 180 or a stationary portion of the lithographic apparatus such as the base frame BF). In an embodiment the second positioner PW is moved under control of the controller 500 thereby to vary the position in the first (z) direction of the substrate support 60 relative to the treatment tool 100. Thereby the force between the substrate support 60 and treatment tool 100 is varied dependent upon the relative position in the x and y directions of the treatment tool 100 relative to the substrate support 60. In an alternative embodiment, particularly suitable for an embodiment in which the system 1 for cleaning the substrate support 60 is outside of the lithographic apparatus, the substrate support 60 is held stationary relative to the remainder of the system 1 for cleaning the substrate W, for example stationary relative to the reference portion 180. In that embodiment the movement of the treatment tool 100 relative to the substrate support 60 is achieved by an actuator applying a force between the reference portion 180 and the treatment tool 100, for example such as the force control element 175. That actuator may either apply the force 201 along the axis of the shaft 150 or apply a force 202 off axis at a plurality of locations on the treatment tool 100.

Like described above in relation to the passive embodiment, in a system 1 for cleaning the substrate support 60 which is outside of the lithographic apparatus a positioner similar to the second position at PW may be used in the active embodiment. Additionally or alternatively the positioner associated with the substrate support 60 may only position in the z direction. Alternatively the substrate support 60 may be in fixed position relative to the reference portion 180 with translational movement in the first, second and third directions of the treatment tool 100 being accomplished by an actuator applying a force between the reference portion 180 and the treatment tool 100.

The actuator may be piezo actuator which can be current or voltage controlled or by an electromagnetic Lorenz actuator or by a pneumatic or hydraulic actuator. These actuators may be placed within or outside of the lithographic apparatus. These actuators may be controlled by feedforward control and/or by feedback control with real time force sensing.

Cleaning of the substrate support 60 may be performed on a pre-determined schedule based on a time or number of substrates W placed on the substrate support 60, for example. In that case the controller 500 controls the force/displacement of the actuator in a feedforward manner dependent upon the position in the x and y directions of the treatment tool 100 relative to the substrate support 60. Cleaning may take place periodically and/or as the result of detection of contamination, for example above a predetermined level, either by direct measurement of the substrate support 60 or during level measurements of a substrate loaded to the substrate support 60.

In an embodiment the substrate support 60 is cleaned using the treatment tool 100 when a measurement step determines deviations from a desired surface topography (deviations or divergences from flatness) of the substrate W supported by the substrate support 60. This may be measured directly or indirectly. For example, before irradiating a substrate in a lithographic apparatus a levelling step is performed during which the surface topography on the substrate support 60 is measured. If deviations in the measured topography are beyond a pre-determined allowable amount, the controller 500 either indicates that cleaning is necessary or automatically initiates a cleaning process. In an alternative or additional embodiment the measuring may be direct measuring of the heights of the terminal surfaces of the projections 20. This may be performed in a lithographic apparatus by a level sensor normally used to measure the surface topography of a substrate W mounted on the substrate support 60. In an embodiment, the deviations are measured once and control of the treatment tool 100 to remove those deviations is determined once. The same control of the treatment tool 100 (e.g. in terms of amount of time at each position and/or force and/or rotation speed variations with position) is then used during subsequent cleaning actions without a step of measuring deviations.

The controller 500 may use the results of the measurement step during the cleaning step. For example, if deviations or divergences from flatness are determined, the force between the treatment tool 100 and substrate support 60 may be varied such that a higher force is applied in positions where the terminal surfaces of the projections 20 have been determined to extend further away from the main body surface 22 than average. In this way the apparatus can be used to increase the flatness of the substrate support 60 and not just to maintain the flatness of the substrate support 60. The skilled person will understand that the same principles can be applied to the embodiment where additionally or alternatively the force and/or the rotation speed and/or amount of time at each position is varied to achieve the same result.

Indeed the present invention may be used solely to increase the flatness of a substrate support 60 that is, in the above described embodiments, the force/displacement of the treatment tool 100 relative to the substrate support 60 is varied to keep the force on each of the projections 20 the same. However, the invention can be used deliberately to apply a greater or lower force than average at specific positions of the treatment tool 100 relative to the substrate support 60 in the second and third (x and y) directions. In this way it is possible to remove more matter from the substrate support 60 in certain locations, in plan, and this could lead to improved flatness of the substrate support 60. The skilled person will understand that the same principles can be applied to the embodiment where additionally or alternatively the force and/or the rotation speed and/or amount of time at each position is varied to achieve the same result.

In an embodiment multiple different treatment tools 100 of different sizes and/or types (e.g. roughness or hardness) can be used to maximize flatness and/or minimize time taken for the cleaning process.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains one or multiple processed layers.

While specific embodiments of the invention have been described above, it will be appreciated that the invention may be practiced otherwise than as described.

Any controllers described herein may each or in combination be operable when the one or more computer programs are read by one or more computer processors located within at least one component of the lithographic apparatus. The controllers may each or in combination have any suitable configuration for receiving, processing, and sending signals. One or more processors are configured to communicate with the at least one of the controllers. For example, each controller may include one or more processors for executing the computer programs that include machine-readable instructions for the methods described above. The controllers may include data storage media for storing such computer programs, and/or hardware to receive such media. So the controller(s) may operate according the machine readable instructions of one or more computer programs.

The descriptions above are intended to be illustrative, not limiting. Thus, it will be apparent to one skilled in the art that modifications may be made to the invention as described without departing from the scope of the claims set out below.

1. A system for cleaning a substrate support comprising a plurality of projections extending in a first direction each with a terminal surface arranged to be in contact with the substrate, the system comprising:
a treatment tool arranged for relative movement in a second direction orthogonal to the first direction and a third direction orthogonal to the first direction and the second direction over the terminal surfaces of the projections for removing matter from the substrate support; and
a controller configured to control the treatment tool dependent upon a position in the second and third directions of the treatment tool relative to the substrate support such that the removal amount from each of the plurality of projections is maintained substantially constant from one projection to another.

2. The system of claim 1, wherein the controller is configured to control a rotation speed of the treatment tool around the first direction dependent upon a position in the second and third directions of the treatment tool relative to the substrate support.

3. The system of claim 1, wherein the controller is configured to control an amount of time the treatment tool is in each position in the second and third directions relative to the substrate support dependent upon a position in the second and third directions of the treatment tool relative to the substrate support.

4. The system of claim 1, further comprising an actuator configured to apply a variable force in the first direction between the treatment tool and the substrate support; and
wherein the controller is configured to control a magnitude of the variable force applied by the actuator dependent upon a position in the second and third directions of the treatment tool relative to the substrate support.

5. The system of claim 2, wherein the controller is configured such that the rotation speed and/or amount of time and/or variable force decreases when the treatment tool moves from a location with a certain number of the plurality of projections under it to a location of with a lower number of the projections under it than the certain number and vice versa.

6. The system of claim 1, wherein the area in a plan extending in the second and third directions of the treatment tool and orthogonal to the first direction is smaller than the area in the plan extending in the second and third directions of the substrate support and orthogonal to the first direction.

7. A lithographic apparatus comprising the system of claim 1.

8. (canceled)

9. A lithographic apparatus comprising:
a substrate support comprising a plurality of projections extending in a first direction each with a terminal surface arranged to be in contact with a substrate to support a substrate;
a treatment tool arranged for relative movement in a second direction orthogonal to the first direction and a third direction orthogonal to the first direction and the second direction over the terminal surfaces of the projections for removing matter from the substrate support;
an actuator configured to move the substrate support and/or treatment tool in the first direction relative to the other of the substrate support and/or treatment tool; and
a controller configured to control the actuator dependent upon a position in the second and third directions of the treatment tool relative to the substrate support.

10. The lithographic apparatus of claim 9, further comprising a passive force control element configured to apply a biasing force in the first direction between the treatment tool and a reference portion which is fixed in the first direction relative to the lithographic apparatus during use of the treatment tool.

11. The lithographic apparatus of claim 10, wherein a magnitude of the biasing force on the treatment tool applied by the passive force control element varies as a function of distance between the treatment tool and the reference portion.

12. The lithographic apparatus of claim 9, wherein the actuator is adapted to move the substrate support in the first direction relative to a projection system during exposure of the substrate.

13. The lithographic apparatus of claim 9, wherein the controller is configured to control the actuator on the basis of a force between the substrate support and the treatment tool.

14. The lithographic apparatus of claim 9, wherein the controller is configured such that a force applied between the treatment tool and the substrate support decreases when the treatment tool moves from a location with a certain number of the plurality of projections under it to a location with a lower number of the plurality of projections under it than the certain number and vice versa.

15. The lithographic apparatus of claim 9, wherein the size in a plane extending in the second and third directions of the treatment tool and orthogonal to the first direction is smaller than the size in the plane extending in the second and third directions of the substrate support and orthogonal to the first direction.

16. A method of removing matter from a substrate support which comprises a plurality of projections extending in a first direction each with a terminal surface arranged to be in contact with the substrate to support the substrate, the method comprising:
moving a treatment tool in a second direction orthogonal to the first direction and a third direction orthogonal to the first direction and the second direction over the terminal surfaces of the projections to remove matter from the substrate support; and
controlling the treatment tool dependent upon a position in the second and third directions of the treatment tool relative to the substrate support such that the removal amount from each of the plurality of projections is maintained substantially constant from one projection to another.

17.-20. (canceled)

21. The method of claim 16, further comprising, before the moving step, a measurement step in which deviations from a desired surface topography of the substrate supported by the substrate support are determined.

22. A method of removing matter from a substrate support which comprises a plurality of projections extending in a first direction each with a terminal surface arranged to be in contact with a substrate to support the substrate, the method comprising:
moving a treatment tool in a second direction orthogonal to the first direction and a third direction orthogonal to the first direction and the second direction over the terminal surfaces of the projections to remove matter from the substrate support;
measuring deviations from a desired surface topography of the substrate supported by the substrate support; and
controlling the treatment tool dependent upon a position in the second and third directions of the treatment tool relative to the substrate support and dependent upon the measured deviation at the position to reduce or maintain differences in measured deviation from one projection to another.

23-28. (canceled)

29. The method of claim 22, wherein the measuring includes measuring divergences from flatness of a substrate supported on the substrate support.

30. The method of claim 22, wherein the measuring includes measuring a position in the first direction of each of the plurality of projections.

31. The method of claim 22, wherein the moving and controlling occurs after deviations above a predetermined level are determined in the measurement step.

32. The method of claim 22, further comprising, before the moving step, a detection step in which contamination of the substrate support is detected and wherein the moving and controlling occurs after contamination above a predetermined level is detected.

33. (canceled)
